(19) United States
(12) Patent Application Publication
(10) Pub. No.: US 2024/0423023 A1
(43) Pub. Date: Dec. 19, 2024

(54) DISPLAY PANEL AND DISPLAY DEVICE

(71) Applicant: Hefei Visionox Technology Co., Ltd., Hefei (CN)

(72) Inventors: Liusong NI, Hefei (CN); Yiming XIAO, Hefei (CN); Yuan YAO, Hefei (CN); Yi-Yu LAI, Hefei (CN); Xuejing ZHU, Hefei (CN)

(73) Assignee: Hefei Visionox Technology Co., Ltd., Hefei (CN)

(21) Appl. No.: 18/654,404

(22) Filed: May 3, 2024

Related U.S. Application Data
(63) Continuation of application No. PCT/CN2023/139037, filed on Dec. 15, 2023.

(30) Foreign Application Priority Data
Jun. 13, 2023 (CN) 202310707209.0

(51) Int. Cl. H10K 59/122

(52) U.S. Cl. CPC H10K 59/122

(57) ABSTRACT

A display panel in the present application includes: a base plate; a plurality of first electrodes disposed on a side of the base plate, first openings are formed between adjacent ones of the first electrodes; an insulation layer disposed on a side of the first electrodes away from the base plate, at least a part of the insulation layer is located within the first openings, the insulation layer includes second openings that run through the insulation layer, and an orthographic projection of the second opening on the base plate overlaps at least partially with an orthographic projection of the first electrode on the base plate; and at least one isolation structure disposed on a side of the insulation layer away from the base plate, an orthographic projection of the first opening on the base plate is located within an orthographic projection of the isolation structure on the base plate.

### CROSS REFERENCE TO RELATED APPLICATIONS

The present application is a continuation of International Application No. PCT/CN2023/139037 filed on Dec. 15, 2023, which claims priority to Chinese patent application No. 202310707209.0, filed on Jun. 13, 2023 and entitled with “DISPLAY PANEL AND DISPLAY DEVICE”, which are incorporated herein by reference in their entireties.

### TECHNICAL FIELD

The present application relates to the field of display technology, in particular to a display panel and a display device.

### BACKGROUND

Technologies of Organic Light Emitting Display (OLED) and flat display devices based on Light Emitting Diode (LED) or the like have been widely used in various consumer electronic products such as mobile phones, televisions, laptops, and desktops, etc. due to their advantages of higher imaging quality, power saving, thinner device body, and wider range of application, and become the mainstream of display devices.

### SUMMARY

In a first aspect, the embodiments of the present application provides a display panel, including: a base plate; a plurality of first electrodes disposed on a side of the base plate, first openings are formed between adjacent ones of the first electrodes; an insulation layer disposed on a side of the first electrodes away from the base plate, at least a part of the insulation layer is located within the first openings, the insulation layer includes second openings that run through the insulation layer, and an orthographic projection of the second opening on the base plate overlaps at least partially with an orthographic projection of the first electrode on the base plate; and at least one isolation structure disposed on a side of the insulation layer away from the base plate, an orthographic projection of the first opening on the base plate is located within an orthographic projection of the isolation structure on the base plate.

In a second aspect, the embodiments of the present application provide a display device, including the display panel according to any of embodiments.

### BRIEF DESCRIPTION OF THE DRAWINGS

FIG. 1 is a schematic top view illustrating a structure of a display panel according to some embodiments of the present application;

FIG. 2 is a schematic and enlarged top view illustrating a structure of the display panel of FIG. 1 in an area B according to an example;

FIG. 3 illustrates a cross-sectional view of the display panel of FIG. 2 along a cross section A-A according to an example;

FIG. 4 illustrates a cross-sectional view of the display panel of FIG. 2 along a cross section A-A according to another example;

FIG. 5 illustrates a cross-sectional view of the display panel of FIG. 2 along a cross section A-A according to another example; and

FIG. 6 illustrates a cross-sectional view of the display panel of FIG. 2 along a cross section A-A according to yet another example.

FIG. 7 illustrates a cross-sectional view of the display panel of FIG. 2 along a cross section A-A according to yet another example.

### EXPLANATIONS OF REFERENCE SIGNS

10. Display panel;

100. Base plate;

200. First electrode; 210. First opening;

300. Insulation layer; 310. Second opening; 320. First recess; 330. Fifth side; 340. Sixth side; 350. Pixel definition unit;

400. Isolation structure; 410. Second recess; 420. Isolation wall; 421. Third recess; 422. First side; 423. Second side; 430. Barrier part; 440. Third side; 450, Fourth side; 460. Isolation opening;

500. Light-emitting functional layer; 510. Light-emitting functional unit; 600. Second electrode;

700. Encapsulation layer; 710. First encapsulation layer; 720. Second encapsulation layer; 730. Third encapsulation layer;

AA, display area; z. Thickness direction of the display panel.

### DETAILED DESCRIPTION

In the disclosure, relational terms such as “first” and “second” are only used to distinguish one entity or operation from another entity or operation, without necessarily requiring or implying any such actual relationship or order between these entities or operations. Moreover, the terms “including”, “comprising”, or any other variation thereof are intended to encompass non-exclusive inclusion, such that a process, method, item, or device that includes a series of elements not only includes those elements, but also includes other elements that are not explicitly listed, or also includes elements inherent to such process, method, item, or device. Without further limitations, elements limited by the statement “including . . . ” do not exclude existence of other elements in the process, method, item, or device that includes the elements.

It should be understood that when describing a structure of an element, reference to one layer or area located “on” or “above” another layer or area may refer to that the layer or area is directly located on the another layer or area, or that there may be any other layer or area between the layer or area and the another layer or area. If the element is flipped, the layer or area will be located “below” or “under” the another layer or area.

In view of the above, the present application proposes a display panel, including: a base plate, a plurality of first electrodes, an insulation layer, and at least one isolation structure. The first electrodes are disposed on a side of the base plate, first openings are formed between adjacent ones of the first electrodes. The insulation layer is disposed on a side of the first electrodes away from the base plate, at least a part of the insulation layer is located within the first openings, the insulation layer includes second openings that run through the insulation layer, and an orthographic projection of the second opening on the base plate overlaps at least partially with an orthographic projection of the first electrode on the base plate. The at least one isolation structure is disposed on a side of the insulation layer away from the base plate, and an orthographic projection of the first opening on the base plate is located within an orthographic projection of the isolation structure on the base plate.

In the embodiments of the present application, the display panel includes a base plate, a plurality of first electrodes, an insulation layer, and at least one isolation structure. The first electrodes are disposed on a side of the base plate, first openings are formed between adjacent ones of the first electrodes. The insulation layer is disposed on a side of the first electrode away from the base plate, at least a part of the insulation layer is located within the first openings, the insulation layer includes second openings that run through the insulation layer, and an orthographic projection of the second opening on the base plate overlaps at least partially with an orthographic projection of the first electrode on the base plate. The at least one isolation structure is disposed on a side of the insulation layer away from the base plate. By making an orthographic projection of the first opening on the base plate to be located within the orthographic projection of the isolation structure on the base plate, that is, extending an edge of the first electrode into a coverage range of the orthographic projection of the isolation structure, a size of the first opening can be reduced, which prevents the insulation layer and in turn the film layer for forming the at least one isolation structure from having undulations in a larger area, and is thus beneficial for preparation of the at least one isolation structure in subsequent processes and improvement of processing properties of the display panel.

In order to better understand the present application, the display panel and display device according to the embodiments of the present application will be described in detail below in conjunction with the accompanying drawings. Here, it is explained that a z-direction in the attached figures represents a thickness direction of the display panel. In the attached figures, for convenience of drawing, dimensions in the figures are not necessarily proportional to actual dimensions, and some hierarchical structures in a display panel are not depicted.

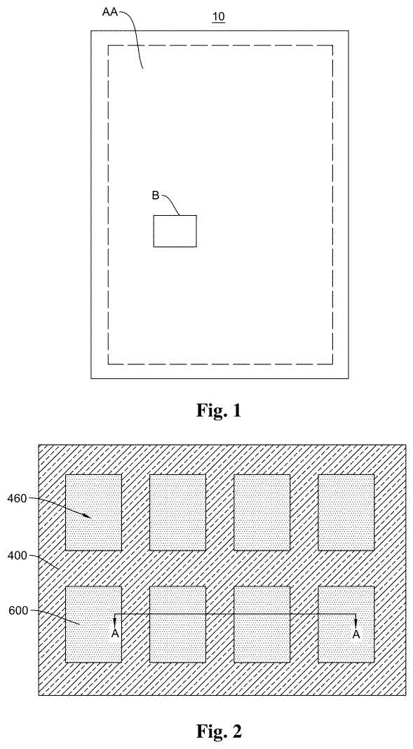

Referring to FIGS. 1 to 3, FIG. 1 is a schematic top view illustrating a structure of a display panel according to some embodiments of the present application; FIG. 2 is a schematic and enlarged top view illustrating a structure of the display panel of FIG. 1 in an area B according to an example; and FIG. 3 illustrates a cross-sectional view of the display panel of FIG. 2 along a cross section A-A according to an example. The area B shown in FIG. 1 is located in a display area AA of the display panel.

As shown in FIGS. 1 to 3, the embodiments of a first aspect of the present application provides a display panel 10, which includes a base plate 100, a plurality of first electrodes 200, an insulation layer 300, and at least one isolation structure 400. The first electrodes 200 are disposed on a side of the base plate 100, first openings 210 are formed between adjacent ones of the first electrodes 200. It should be noted that the first openings 210 being formed between adjacent ones of the first electrodes 200 is discussed here by references to the cross-sectional view of the display panel, and actually the first openings are substantively formed by being surrounded by the first electrodes and connected together as a larger opening like a grid mesh, as viewed in a top view. The insulation layer 300 is disposed on a side of the first electrodes 200 away from the base plate 100, at least a part of the insulation layer 300 is located within the first openings 210, the insulation layer 300 includes second openings 310 that runs through the insulation layer 300, and an orthographic projection of the second opening 310 on the base plate 100 overlaps at least partially with an orthographic projection of the first electrode 200 on the base plate, and the orthographic projection of the second opening 310 on the base plate 100 is offset from an orthographic projection of the first opening 210 on the base plate 100. The at least one isolation structure 400 is disposed on a side of the insulation layer 300 away from the base plate 100, the orthographic projection of the first opening 210 on the base plate 100 is located within an orthographic projection of the isolation structure 400 on the base plate 100. It should be noted that the at least one isolation structure 400 is discussed here by references to the cross-sectional view of the display panel, and may include one or more isolation structures 400, and the at least one isolation structure 400 may be connected together as a larger isolation structure like a grid mesh, as viewed in the top view shown in FIG. 2. In related arts, due to presence of the first openings 210, the insulation layer 300 may experience undulations on its side away from the first electrodes 200 at positions corresponding to the first openings 210. If the orthographic projection of the first opening 210 on the base plate 100 is not located within the orthographic projection of the isolation structure 400 on the base plate 100, that is, the first opening 210 is larger, the insulation layer 300 covering the first openings 210 will have undulations in a larger area, and in turn an isolation structure film layer formed on the insulation layer 300 will have undulations in a larger area, which is not conducive to preparation of the at least one isolation structure 400 in subsequent processes. For example, in the case where an entire isolation structure film layer has been formed but the at least one isolation structure 400 have not been formed, an edge of the isolation structure 400 to be formed will be at or near an undulating position of the isolation structure film layer, which will affect preparation of the isolation structure 400 and in turn processing properties of the display panel.

In the this embodiment of the present application, the orthographic projection of the first opening 210 on the base plate 100 is located within the orthographic projection of the isolation structure 400 on the base plate 100, such that an edge of the first electrode 200 is extended into a coverage range of the isolation structure 400, which reduces a size of the first opening 210, and thus reduces the area where the insulation layer 300 may have undulations and prevents the isolation structure film layer from having undulations in a larger area, and thereby is beneficial for preparation of the isolation structure in subsequent processes and improvement of processing properties of the display panel.

In some embodiments, first recesses 320 may be formed on the side of the insulation layer 300 away from the base plate 100, an orthographic projection of the first recess 320 on the base plate 100 overlaps at least partially with the orthographic projection of the first opening 210 on the base plate 100, and at least a part of the isolation structure 400 is located within the first recess 320.

In some embodiments, at least a part of the insulation layer 300 is located within the first openings 210, such that the first recesses 320 are formed on the side of the insulation layer 300 away from the base plate 100.

In some embodiments, the insulation layer 300 may include a fifth side 330 and a sixth side 340, wherein the fifth side 330 is an upper surface of the insulation layer 300 away from the base plate 100, and the sixth side 340 is a lower surface of the insulation layer 300 facing the base plate 100, and an orthographic projection of the fifth side 330 on the base plate 100 is located within an orthographic projection of the sixth side 340 on the base plate 100, and the orthographic projection of the first opening 210 on the base plate 100 is located within the orthographic projection of the fifth side 330 on the base plate 100.

In the display panel 10 provided in the this embodiment of the present application, the orthographic projection of the first opening 210 is located within the orthographic projection of the fifth side 330 on the base plate 100, that is, an edge of the first electrode 200 is extended into a coverage range of the fifth side 330, such that an edge of the first electrode 200 is offset from an edge of the insulation layer 300, which refers to a boundary between the fifth surface 330 and a side surface of the insulation layer 300, which reduces undulating areas of the insulation layer 300, and is beneficial for preparation of the isolation structure 400 in subsequent processes and improvements processing properties of the display panel.

In some embodiments, second recesses 410 are formed on a side of the isolation structure 400 away from the base plate 100, and an orthographic projection of the second recess 410 on the base plate 100 overlaps at least partially with the orthographic projection of the first recess 320 on the base plate 100.

In some embodiments, the orthographic projection of the second recess 410 on the base plate 100 overlaps at least partially with the orthographic projection of the first opening 210 on the base plate 100.

In the display panel 10 provided in the this embodiment of the present application, at least a part of the insulation layer 300 is located within the first openings 210, such that the first recesses 320 are formed on the side of the insulating layer 300 away from the base plate 100, and at least a part of the isolation structure 400 is located within the first recesses 320, such that the second recesses 410 are formed on the side of the isolation structure 400 away from the base plate 100.

In some embodiments, the isolation structure 400 may include an isolation wall 420 disposed on the side of the insulation layer 300 away from the base plate 100, at least a part of the isolation wall 420 is located within the first recess 320, a third recess 421 is formed on a side of the isolation wall 420 away from the base plate 100, and an orthographic projection of the third recess 421 on the base plate 100 overlaps at least partially with the orthographic projection of the first recess 320 on the base plate 100.

In some embodiments, the isolation structure 400 may further include a barrier part 430 disclosed on the side of the isolation wall 420 away from the base plate 100, an orthographic projection of the isolation wall 420 on the base plate 100 is located within an orthographic projection of the barrier part 430 on the base plate 100, at least a part of the barrier part 430 is located within the third recess 421, the second recess 410 is located on a side of the barrier part 430 away from the isolation wall 420, and the orthographic projection of the second recess 410 on the base plate 100 overlaps at least partially with the orthographic projection of the third recess 421 on the base plate 100.

In some embodiments, both the isolation wall 420 and the barrier part 430 may include metal materials, and further, the isolation wall 420 and the barrier part 430 may include different metal materials. For example, the isolation wall 420 may include aluminum, while the barrier part 430 may include titanium. Of course, the materials of the isolation wall 420 and the barrier part 430 are not limited to these materials, but may include other types of metal materials, which is not particularly limited. For better explanations, the embodiments of the present application will be described below using an example where the isolation wall 420 includes aluminum and the barrier part 430 includes titanium.

After forming a metal aluminum layer of the isolation wall 420 and a metal titanium layer of the barrier part 430 but before forming the isolation wall 420 and the barrier part 430, the metal aluminum layer and the metal titanium layer may be processed in a dry etching and then in a wet etching to form the isolation structure 400 in the shape of eaves. By extending the edge of the first electrode 200 into the coverage range of the barrier part 430, an influence of undulations of the metal aluminum layer and the metal titanium layer on the dry etching can be reduced, and thus effects of the dry etching can be improved.

In some embodiments, the orthographic projection of the third recess 421 on the base plate 100 overlaps at least partially with the orthographic projection of the first opening 210 on the base plate 100.

In the display panel 10 provided in the this embodiment of the present application, at least a part of the insulation layer 300 is located within the first openings 210 such that the first recesses 320 are formed on the side of the insulation layer 300 away from the base plate 100, at least a part of the isolation wall 420 is located within the first recess 320 such that a third recess 421 is formed on the side of the isolation wall 420 away from the base plate 100, and at least a part of the barrier part 430 is located within the third recess 421 such that the second recess 410 is formed on the side of the barrier part 430 away from the base plate 100.

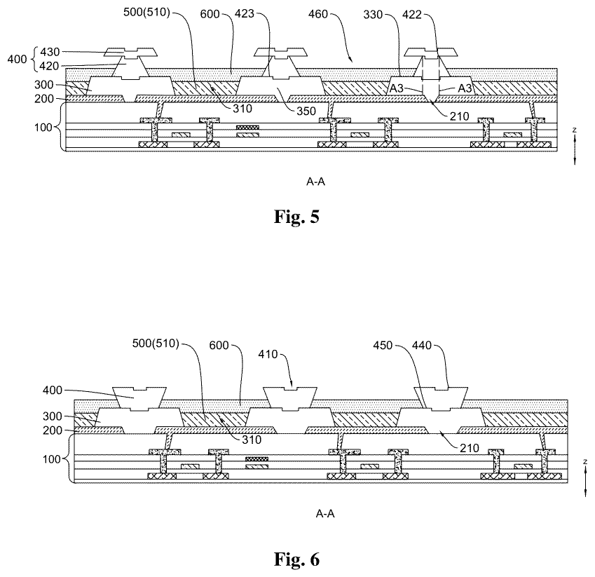

Referring to FIGS. 3 to 5, FIG. 4 illustrates a cross-sectional view of the display panel of FIG. 2 along a cross section A-A according to another example; and FIG. 5 illustrates a cross-sectional view of the display panel of FIG. 2 along a cross section A-A according to another example.

As shown in FIG. 3, in some embodiments, the orthographic projection of the isolation wall 420 on the base plate 100 is located within the orthographic projection of the barrier part 430 on the base plate 100, and the orthographic projection of the first opening 210 on the base plate 100 is located within the orthographic projection of the barrier part 430 on the base plate 100. The dashed lines A1 in FIG. 3 are not physical connection lines, but projection lines for the orthographic projection of the barrier part 430 on the base plate 100. The orthographic projection of the barrier part 430 on the base plate 100 can be understood as a region between the two dashed lines A1 in FIG. 3.

The isolation structure 400 can be used instead of a metal mask plate, which reduces costs for providing a set of molds and improves pixel density of the display panel 10. By forming the rooflike barrier part 430, it makes the devices are independent from each other, which further optimizes optical performance of the display panel 10. The orthographic projection of the first opening 210 on the base plate 100 is located within the orthographic projection of the barrier part 430 on the base plate 100, which means the edge of the first electrode 200 is extended into a coverage range of the barrier part 430, which reduces the area where the insulation layer 300 may have undulations and prevents the isolation structure film layer from having undulations in a larger area, and thereby is beneficial for preparation of the isolation structure in subsequent processes and improvement of processing properties of the display panel.

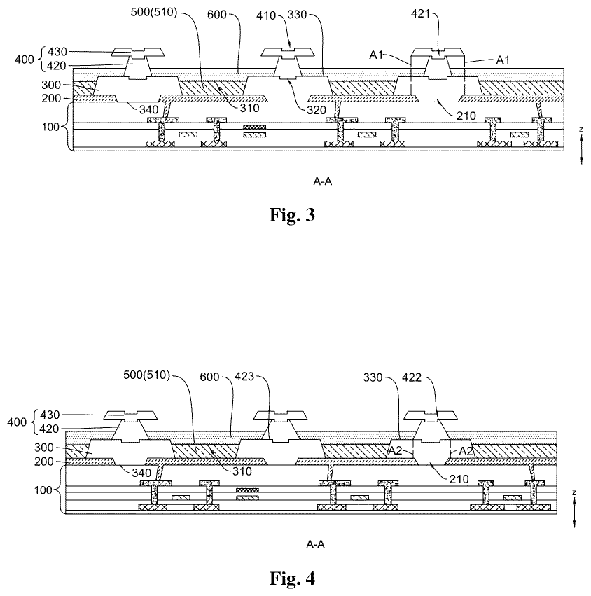

As shown in FIG. 4, in some embodiments, the orthographic projection of the first opening 210 is located within the orthographic projection of the isolation wall 420 on the base plate 100.

In some embodiments, the isolation wall 420 may include a first surface 422 and a second surface 423, one of which is a lower surface facing toward the base plate 100 and the other is an upper surface away from the base plate 100, an orthographic projection of the first surface 422 on the base plate 100 is located within an orthographic projection of the second side 423 on the base plate 100, and the orthographic projection of the first electrode 200 on the base plate 100 overlaps at least partially with the an orthographic projection of the second side 423 on the base plate 100. The dashed lines A2 in FIG. 4 are not physical connection lines, but projection lines for the orthographic projection of the second side 423 on the base plate 100. The orthographic projection of the second side 423 on the base plate 100 can be understood as a region between the two dashed lines A2 in FIG. 4.

By making that the orthographic projection of the first electrode 200 on the base plate 100 overlaps at least partially with the orthographic projection of the second side 423 on the base plate 100, that is, the orthographic projection of the first opening 210 on the base plate 100 is located within the orthographic projection of the second side 423 on the base plate 100, the edge of the first electrode 200 is extended into a coverage range of the isolation wall 420, which reduces the size of the first opening 210, and in turn undulating areas of the insulation layer 300, and thereby uniformity in dimension of the isolation structure 400 (such as height of the isolation structure) can be improved, and display effects of the display panel 10 can be improved. As shown in FIG. 5, in some embodiments, the orthographic projection of the first electrode 200 on the base plate 100 overlaps at least partially with the orthographic projection of the first side 422 on the base plate 100, that is the orthographic projection of the first opening 210 on the base plate 100 is located within the orthographic projection of the first side 422 on the base plate 100. The dashed lines A3 in FIG. 5 are not physical lines, but projection lines for the orthographic projection of the first side 422 on the base plate 100. The orthographic projection of the first side 422 on the base plate 100 can be understood as a region between the two dashed lines A3 in FIG. 5. Undulating areas of the insulation layer 300 can thus be reduced, uniformity in dimension of the isolation structure 400 can be improved, and display effects of the display panel 10 can be improved.

In some embodiments, the first side 422 is the upper surface of the isolation wall 420 away from the base plate 100, and the second side 423 is the lower surface of the isolation wall 420 facing the base plate 100.

In some embodiments, an orthographic projection of an upper surface of the isolation wall 420 on the base plate 100 is located within an orthographic projection of a lower surface of the isolation wall 420 on the base plate 100, and the orthographic projection of the first opening 210 on the base plate 100 is located within the orthographic projection of the upper surface of the isolation wall 420 on the base plate 100.

In some embodiments, the isolation wall 420 may include a conductive material.

In some embodiments, the display panel 10 further includes a light-emitting functional layer 500 and a plurality of second electrodes 600. The light-emitting functional layer 500 includes a plurality of light-emitting functional parts 510, each of the light-emitting functional parts is located within each of the second openings 310. The second electrodes 600 are disposed on a side of the light-emitting functional layer 500 away from the base plate 100, at least a part of the second electrode 600 is located within the second opening 310. The first electrode 200 and the second electrode 600 are electrically connected with the light-emitting functional part 510, and the second electrode 600 and the first electrode 200 are used to provide power for the light-emitting functional part 510 and drive it to emit light. Specifically, one of the first electrode 200 and the second electrode 600 functions as an anode and the other functions as a cathode. The embodiments of the present application will be described with an example where the second electrode 600 functions as the cathode and the first electrode 200 functions as the anode.

The light-emitting functional layer 500 may include film layer structures such as a hole injection layer (HIL), a hole transport layer (HTL), a light-emitting material layer (EL), an electron transport layer (ETL), and an electron injection layer (EIL) that are sequentially stacked. The light emitting material layer (EL) may include a light-emitting material for red sub-pixels, a light-emitting material for green sub-pixels, and a light-emitting material for blue sub-pixels.

In some embodiments, the isolation structure 400 is located between adjacent ones of the light-emitting functional parts 510.

In some embodiments, due to presence of the isolation structure 400, the isolation structure 400 can not only make the light-emitting functional layer 500 to be partitioned but also make a second electrode layer to be partitioned to form the second electrodes 600.

In some embodiments, the second electrodes 600 are partitioned by the isolation structure 400, so the second electrodes 600 can be independently controlled.

In some embodiments, the second electrodes 600 are partitioned by the isolation structure 400, but may be electrically connected through other components. For example, the second electrodes 600 may be in contact and connected with the isolation structure 400, such that at least the second electrodes within two adjacent ones of the second openings 310 may be electrically connected through the isolation structure 400.

The isolation structure 400 may have a conductive material, and the second electrodes 600 within at least two adjacent ones of the second openings 310 are electrically connected through the conductive material of the isolation structure 400. Due to good dimensional uniformity of the isolation structure 400 in the above embodiment, the second electrodes 600 can be easily connected to the conductive material of the isolation structure 400 to achieve electrical connection between adjacent second electrodes 600 through the conductive material of the isolation structure 400.

For example, the second electrodes 600 within at least two adjacent ones of the second openings 310 may be electrically connected through the isolation wall 420. Due to good dimensional uniformity of the isolation structure 400, the second electrodes 600 can thus be easily connected to the isolation wall 420.

In the display panel 10 provided in this embodiment of the present application, the second electrodes 600 within two adjacent ones of the second openings 310 are electrically connected through the isolation structure 400, so that the display panel 10 can achieve regional or overall connectivity.

Continuing to refer to FIGS. 2 and 5, in some embodiments, the orthographic projection of the at least one isolation structure 400 on the base plate 100 may like a grid mesh. That is, the at least one isolation structure 400 may be integrally formed like that as shown in FIG. 2. The isolation structure 400 may isolate the light-emitting functional parts 510 from each other. For example, the isolation structure 400 may isolate the light-emitting functional parts 510 of respective sub-pixels from each other. The isolation structure 400 may isolate the light-emitting functional parts 510 of a group of sub-pixels from each other. For example, the isolation structure 400 may isolate the light-emitting functional parts 510 of a group of sub-pixels of the same color from each other.

In some embodiments, isolation openings 460 are formed by being surrounded by the at least one isolation structure 400, an orthographic projection of the isolation opening 460 on the base plate 100 overlaps at least partially with the orthographic projection of the second opening 310 on the base plate 100, and the orthographic projection of the isolation opening 460 on the base plate 100 is offset from the orthographic projection of the first opening 210 on the base plate 100.

In some embodiments, the insulation layer 300 may include a pixel definition layer, and the pixel definition layer includes pixel definition parts 350, and the second openings 310 are formed being surrounded by the pixel definition parts 350.

In some embodiments, a distance between adjacent ones of the first electrodes 200 may be greater than or equal to 5 μm.

In the display panel 10 provided in this embodiment, by setting the distance between adjacent ones of the first electrodes 200 to be greater than or equal to 5 μm, a probability of adjacent first electrodes 200 being connected as a whole during preparation can be reduced, thereby reducing difficulty in forming the first openings 210.

Referring to FIG. 6, which illustrates a cross-sectional view of the display panel of FIG. 2 along a cross section A-A according to yet another example.

As shown in FIG. 6, in some embodiments, the isolation structure 400 may include a third side 440 and a fourth side 450, the third side 440 is an upper surface of the isolation structure 400 away from the base plate 100, the fourth side 450 is a lower surface of the isolation structure 400 facing toward the base plate 100, and an orthographic projection of the fourth side 450 on the base plate 100 is located within an orthographic projection of the third side 440 on the base plate 100, and the orthographic projection of the first electrode 200 on the base plate 100 overlaps at least partially with the orthographic projection of the fourth side 450 on the base plate 100.

In some embodiments, the orthographic projection of the first opening 210 on the base plate 100 is located within the orthographic projection of the fourth side 450 on the base plate 100, such that an edge of the first electrode 200 is extended into a coverage range of the isolation structure 400, reducing undulant areas of the insulation layer 300, and improving processing properties of the display panel.

In some embodiments, the isolation structure 400 may have an inverted trapezoid cross-section in a thickness direction (z-direction in the figure) of the display panel 10. By making the cross-section of the isolation structure 400 in the thickness direction z of the display panel 10 to be an inverted trapezoid, the devices are thus independent from each other to optimize optical performance of the display panel 10, and the light-emitting functional parts 510 can thus be packaged independently to improve packaging reliability of the display panel 10.

In some embodiments, the isolation structure 400 may be an integrated structure, and may be an inverted trapezoidal structure formed through etching. The second recess 410 is formed on the third side 440.

In some embodiments, the base plate 100 may include a substrate and a circuit layer, and the circuit layer may include a driving circuit. For example, the circuit layer may include a first conductive layer, a second conductive layer, and a third conductive layer stacked on a side of the substrate. Insulation layers are disposed between adjacent conductive layers. Exemplarily, a pixel driving circuit disposed in the circuit layer includes a transistor and a storage capacitor. The transistor include semiconductor, and includes gate, source and drain terminals. The storage capacitor includes a first electrode plate and a second electrode plate. As an example, the gate terminal and the first electrode plate may be placed in the first conductive layer, the second electrode plate may be placed in the second conductive layer, and the source and drain terminals may be placed in the third conductive layer.

As shown in FIGS. 1 to 6, embodiments of a second aspect of the present application provides a display panel 10, which includes: a base plate 100, a plurality of first electrodes 200, an insulation layer 300, and at least one isolation structure 400. The first electrodes 200 are disposed on a side of the base plate 100 and spaced apart from each other. The insulation layer 300 is disposed on a side of the first electrodes 200 away from the base plate 100, and the insulation layer 300 includes second openings 310 that runs through the insulation layer 300 and an orthographic projection of the second opening 310 on the base plate 100 overlaps at least partially with an orthographic projection of the first electrode 200 on the base plate 100. The isolation structure 400 is disposed on a side of the insulation layer 300 away from the base plate 100, and an orthographic projection of the isolation structure 400 on the base plate 100 overlaps at least partially with the orthographic projection of the first electrode 200 on the base plate 100.

In some embodiments, the isolation structure 400 may include an isolation wall 420 and a barrier part 430. The isolation wall 420 is disposed on a side of the insulation layer 300 away from the base plate 100. The barrier part 430 is disposed on a side of the isolation wall 420 away from the base plate 100, wherein an orthographic projection of the isolation wall 420 on the base plate 100 is located within an orthographic projection of the barrier part 430 on the base plate 100, and the orthographic projection of the barrier part 430 on the base plate 100 overlaps at least partially with the orthographic projection of the first electrode 200 on the base plate 100.

In some embodiments, the orthographic projection of the isolation wall 420 on the base plate 100 overlaps at least with the orthographic projection of the first electrode 200 on the base plate 100.

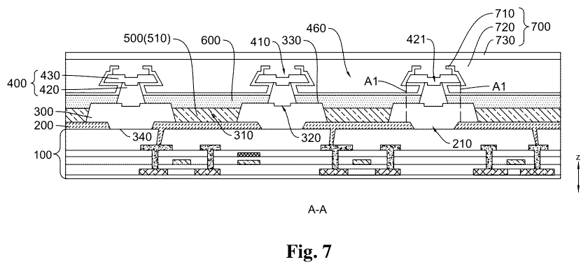

Please referring to FIG. 7, it illustrates a cross-sectional view of the display panel of FIG. 2 along a cross section A-A according to yet another example.

As shown in FIG. 7, in some embodiments, the display panel 10 may further include an encapsulation layer 700 disposed on the side of the second electrodes 600 away from the base plate 100 and being in contact with at least a part of the isolation structure 400.

In some embodiments, orthographic projections of the isolation openings 460 on the base plate 100 is located within an orthographic projection of the encapsulation layer 700 on the base plate 100. The encapsulation layer 700 encapsulates the isolation openings 460, to reduce oxidative erosion of external water vapor on components within the isolation openings 460, thereby improving lifespan of the display panel 10.

In the display panel 10 provided according to the embodiment of the present application, the encapsulation layer 700 disposed on the side of the second electrodes 600 away from the base plate 100 is provided to protect the second electrodes 600 and the light-emitting functional layer 500 from oxidative erosion, thereby improving the lifespan of the display panel 10.

In some embodiments, the encapsulation layer 700 may include a first encapsulation layer 710, which is in contact with and connected to at least a part of the isolation structure 400, and the orthographic projections of the isolation openings 460 on the base plate 100 is located within the orthographic projection of the first encapsulation layer 710 on the base plate 100.

In some embodiments, the first encapsulation layer 710 may be in contact with and connected to a side wall of the isolation structure 400, or even extended toward a side of the isolation structure 400 away from the base plate 100.

In some embodiments, the first encapsulation layer 710 may include an inorganic material, that is, the first encapsulation layer 710 may be an inorganic encapsulation layer. The inorganic encapsulation layer is suitable to be prepared by a chemical vapor deposition method, which can improve density of the first encapsulation layer 710 and thus enhance encapsulation effects of the encapsulation layer 700.

In some embodiments, the encapsulation layer 700 may further include a second encapsulation layer 720 disposed on a side of the first encapsulation layer 710 away from the base plate 100. The second encapsulation layer 720 may include an organic material, that is, the second encapsulation layer 720 may be an organic encapsulation layer, which is suitable to be prepared by an inkjet printing method, which ensures an appropriate thickness of the encapsulation layer 700.

In some embodiments, the encapsulation layer 700 may further include a third encapsulation layer 730 disposed on a side of the second encapsulation layer 720 away from the base plate 100. The third encapsulation layer 730 may include an inorganic material, that is, the third encapsulation layer 730 may be an inorganic encapsulation layer. By adding such additional inorganic encapsulation layer on the organic encapsulation layer, it can further improve encapsulation effects of the encapsulation layer 700. The third encapsulation layer 730 may include the same material as the first encapsulation layer 710 such that the third encapsulation layer 730 can be prepared with a same equipment as that for the first encapsulation layer 710, which can simplify preparation processes of the display panel.

Further, embodiments of a third aspect of the present application provides a display device, which includes a display panel according to any of the foregoing embodiments. Since the display device provided in the embodiments of the third aspect of the present application includes a display panel according to the foregoing embodiments, the display device provided in the embodiments of the third aspect of the present application has same beneficial effects as the display panel according to any of the foregoing embodiments, which will not be further elaborated here.

The display device in the present embodiment includes, but is not limited to, a device with a display function such as a mobile phone, a Personal Digital Assistant (PDA), a tablet, an e-book, a televisions, an access control, a smart landline phones, a consoles, etc.

Although the present application has been described with reference to preferred embodiments, various improvements can be made and components can be replaced with equivalents without departing from the scope of the present application. Especially, as long as there is no structural conflict, the various technical features mentioned in each embodiment can be combined in any way. The present application is not limited to the specific embodiments disclosed in the text, but includes all technical solutions falling within the scope of the claims.

What is claimed is:

1. A display panel, comprising:
a base plate;
a plurality of first electrodes disposed on a side of the base plate, first openings are formed between adjacent ones of the first electrodes;
an insulation layer disposed on a side of the first electrodes away from the base plate, at least a part of the insulation layer is located within the first openings, the insulation layer comprises second openings that run through the insulation layer, and an orthographic projection of the second opening on the base plate overlaps at least partially with an orthographic projection of the first electrode on the base plate; and
at least one isolation structure disposed on a side of the insulation layer away from the base plate, an orthographic projection of the first opening on the base plate is located within an orthographic projection of the isolation structure on the base plate.

2. The display panel according to claim 1, wherein the isolation structure comprises:
an isolation wall disposed on a side of the insulation layer away from the base plate;
a barrier part disposed on a side of the isolation wall away from the base plate, an orthographic projection of the isolation wall on the base plate is located within an orthographic projection of the barrier part on the base plate, and the orthographic projection of the first opening on the base plate is located within the orthographic projection of the barrier part on the base plate.

3. The display panel according to claim 2, wherein the orthographic projection of the first opening on the base plate is located within the orthographic projection of the isolation wall on the base plate.

4. The display panel according to claim 2, wherein the isolation wall comprises a first side and a second side, one of which is a lower surface facing the base plate and the other is an upper surface away from the base plate, an orthographic projection of the first side on the base plate is located within an orthographic projection of the second side on the base plate, and the orthographic projection of the first electrode on the base plate overlaps at least partially with the orthographic projection of the second side on the base plate.

5. The display panel according to claim 4, wherein the orthographic projection of the first electrode on the base plate overlaps at least partially with the orthographic projection of the first side on the base plate.

6. The display panel according to claim 4, wherein the first side is the upper surface of the isolation wall away from the base plate, and the second side is the lower surface of the isolation wall facing the base plate.

7. The display panel according to claim 2, wherein an orthographic projection of an upper surface of the isolation wall on the base plate is located within an orthographic projection of a lower surface of the isolation wall on the base plate, and the orthographic projection of the first opening on the base plate is located within the orthographic projection of the upper surface of the isolation wall on the base plate.

8. The display panel according to claim 1, wherein the isolation structure comprises a third side and a fourth side, the third side is an upper surface of the isolation structure away from the base plate, the fourth side is a lower surface of the isolation structure facing the base plate, and an orthographic projection of the fourth side on the base plate is located within an orthographic projection of the third side on the base plate, and the orthographic projection of the first electrode on the base plate overlaps at least partially with the orthographic projection of the fourth side on the base plate.

9. The display panel according to claim 8, wherein the orthographic projection of the first opening on the base plate is located within the orthographic projection of the fourth side on the base plate; and
the isolation structure has an inverted trapezoid cross-section in a thickness direction of the display panel.

10. The display panel according to claim 1, wherein the orthographic projection of the second opening on the base plate is offset from the orthographic projection of the first opening on the base plate;
the insulation layer comprises a fifth side and a sixth side, wherein the fifth side is a side of the insulation layer away from the base plate, and the sixth side is a side of the insulation layer close to the base plate, and
an orthographic projection of the fifth side on the base plate is located within an orthographic projection of the sixth side on the base plate, and the orthographic projection of the first opening on the base plate is located within the orthographic projection of the fifth side on the base plate.

11. The display panel according to claim 1, wherein first recesses are formed on the side of the insulation layer away from the base plate, an orthographic projection of the first recess on the base plate overlaps at least partially with the orthographic projection of the first opening on the base plate, and at least a part of the isolation structure is located within the first recess.

12. The display panel according to claim 11, wherein a second recess is formed on a side of the isolation structure away from the base plate, and an orthographic projection of the second recess on the base plate overlaps at least partially with the orthographic projection of the first recess on the base plate.

13. The display panel according to claim 12, wherein the orthographic projection of the second recess on the base plate overlaps at least partially with the orthographic projection of the first opening on the base plate.

14. The display panel according to claim 12, wherein the isolation structure comprises:
an isolation wall disposed on the side of the insulation layer away from the base plate, at least a part of the isolation wall is located within the first recess, a third recess is formed on a side of the isolation wall away from the base plate, and an orthographic projection of the third recess on the base plate overlaps at least partially with the orthographic projection of the first recess on the base plate.

15. The display panel according to claim 14, wherein the isolation structure further comprises:
a barrier part disclosed on the side of the isolation wall away from the base plate, an orthographic projection of the isolation wall on the base plate is located within an orthographic projection of the barrier part on the base plate, at least a part of the barrier part is located within the third recess, the second recess is located on a side of the barrier part away from the isolation wall, and the orthographic projection of the second recess on the base plate overlaps at least partially with the orthographic projection of the third recess on the base plate; and
the orthographic projection of the third recess on the base plate overlaps at least partially with the orthographic projection of the first opening on the base plate.

16. The display panel according to claim 1, further comprising:
a light-emitting functional layer including a plurality of light-emitting functional parts, each of the light-emitting functional parts is located within each of the second openings;
a plurality of second electrodes disposed on a side of the light-emitting functional layer away from the base plate, at least a part of the second electrode is located within the second opening;
the isolation structure is located between adjacent ones of the light-emitting functional parts; and
the second electrodes are in contact and connected with the isolation structure such that at least the second electrodes within two adjacent ones of the second openings are electrically connected through the isolation structure.

17. A display panel comprising:
a base plate;
a plurality of first electrodes disposed on a side of the base plate and spaced apart from each other;
an insulation layer disposed on a side of the first electrodes away from the base plate, the insulation layer comprises second openings that run through the insulation layer, and an orthographic projection of the second opening on the base plate overlaps at least partially with an orthographic projection of the first electrode on the base plate; and
at least one isolation structure disposed on a side of the insulation layer away from the base plate, wherein an orthographic projection of the isolation structure on the base plate overlaps at least partially with the orthographic projection of the first electrode on the base plate.

18. The display panel according to claim 17, wherein the isolation structure comprises:
an isolation wall disposed on a side of the insulation layer away from the base plate; and
a barrier part disposed on a side of the isolation wall away from the base plate, an orthographic projection of the isolation wall on the base plate is located within an orthographic projection of the barrier part on the base plate, and the orthographic projection of the barrier part on the base plate overlaps at least partially with the orthographic projection of the first electrode on the base plate.

19. The display panel according to claim 18, wherein the orthographic projection of the isolation wall on the base plate overlaps at least partially with the orthographic projection of the first electrode on the base plate.

20. A display device, comprising the display panel according to claim 1.
